(19) United States
(12) Patent Application Publication
(10) Pub. No.: US 2009/0297791 A1
(43) Pub. Date: Dec. 3, 2009

(54) PATTERNING NANOTUBES WITH VAPOR DEPOSITION

(75) Inventors: Christopher Y. Li, Bala Cynwyd, PA (US); Lingyu Li, Lake Jackson, TX (US)

Correspondence Address: KNOBLE, YOSHIDA & DUNLEAVY, EIGHT PENN CENTER, SUITE 1350, 1628 JOHN F KENNEDY BLVD, PHILADELPHIA, PA, 19103, US

(73) Assignee: DREXEL UNIVERSITY, PHILADELPHIA, PA (US)

(21) Appl. No.: 12/297,473

(22) PCT Filed: Apr. 20, 2007
(86) PCT No.: PCT/US07/67066

§ 371 Date: Jan. 23, 2009

Related U.S. Application Data
(60) Provisional application No. 60/793,880, filed on Apr. 21, 2006.

(51) Int. Cl. B32B 3/14; C23C 14/34

(52) U.S. Cl. 428/195.1; 204/192.15; 977/890

(57) ABSTRACT

A process for the modification of carbon-containing substrates, including 1-dimensional nanowire and nanofiber structures. In the process, polymeric material is deposited on a surface of the carbon containing-substrates using physical vapor deposition. The deposition process may be carried out under controlled conditions to produce a variety of useful modifications, including modifications at discrete intervals, as well as functional modifications. Also disclosed are carbon fibers, carbon nanowires, carbon nanotubes and nano-hybrid structures made by the modification processes of the present invention.

### CROSS-REFERENCE TO RELATED APPLICATIONS

This application claims benefit under 35 U.S.C. §119(e) of the Paris Convention of U.S. Provisional Application No. 60/793,880, filed Apr. 21, 2006, the entire disclosure of which is hereby incorporated by reference as if set forth fully herein.

### STATEMENT OF GOVERNMENT INTEREST

This invention was reduced to practice with Government support under Grant No. 0239415 awarded by the National Science Foundation; the Government is therefore entitled to certain rights to this invention.

### BACKGROUND OF THE INVENTION

1. Field of the Invention

The present invention relates to the provision of modified carbon nanotubes. More particularly, the present invention relates to the use of physical vapor deposition to modify carbon nanotubes, including 1-dimensional nanowire and nanofiber structures, and to the resultant modified carbon nanotubes.

2. Description of the Related Technology

Periodic patterning on one-dimensional (1D) carbon nanotubes (CNTs) is of great interest from both scientific and technological points of view. Periodically patterned CNTs could lead directly to controlled two-dimensional (2D) or three-dimensional (3D) CNT supra-structures, a step toward building future CNT-based nanodevices. Although both chemical and non-covalent CNT functionalization have attracted extensive attention during the past decades, (Chen, J., et al., Science, 1998, 282, 95-98; Hirsch, A., Angew. Chem., Int. Ed., 2002, 41, 1853-1859; Sun, Y. et al., Acc. Chem. Res., 2002, 35, 1096-1104; and Banerjee, S. et al., Adv. Mater., 2005, 17, 17-29), very few efforts have been dedicated to periodically patterning on individual CNTs. Czerw et al. demonstrated regular organization of poly-(propionylethylenimine-co-ethylenimine) (PPEI-EI) on CNTs using scanning tunneling microscopy (STM). See Czerw, R. et al., Nano Lett., 2001, 1, 423-427. CNT electronic structure change upon attachment of polymers was also reported. See Bekyarova, E. et al., J. Am. Chem. Soc., 2005, 127, 5990-5995; and Balasubramanian, K. et al., Adv. Mater., 2003, 15, 1515-1518. Single-stranded DNA (ssDNA) and proteins have been bound to CNTs, resulting in periodic helical wrapping on the surface of CNTs. See Balavoine, F. et al., Angew. Chem., Int. Ed., 1999, 38, 1912-1915; Zheng, M. et al., Science, 2003, 302, 1545-1548; Heller, A. A. et al., Science, 2006, 311, 508-511. Helical wrapping SWNT with starch has also been reported. Star, A. et al., Angew. Chem., Int. Ed., 2002, 41, 2508-2512; and Kim, O. K. et al., J. Am. Chem. Soc., 2002, 125, 4426-4427. Periodic patterning of functionalized SWNTs using the Bingel reaction was examined by Worsley et al. using STM, and the occurrence of highly regular (periodicity 4.6 nm), long-range patterns was attributed to spatial fluctuation of electron density induced long-range reactivity. Worsley, K. A. et al., Nano Lett., 2004, 4, 1541-1546. Recently, use of a controlled polymer solution crystallization method to achieve periodically decorated CNTs and CNFs was reported. Li, C. Y. et al., Adv. Mater., 2005, 17, 1198-1202 ; and Li, L. et al., J. Am. Chem. Soc., 2006, 128, 1692-1699. Polyethylene (PE) and Nylon 6,6 single crystals were grown on CNTs, forming a unique nanohybrid shish kebab (NHSK) structure. In a NHSK structure, polymer single crystals are periodically strung along the CNT axis; CNT forms the “shish” while polymer single crystals form the “kebabs.” Periodicity can be controlled by tuning crystallization conditions.

In a solution-formed NHSK structure, the 2D lamellar (kebab) normal is parallel to the 1D tubes, thereby providing a 3D structure to the NHSK. The 3D structure is advantageous for a number of applications such as nano-composites. In other fields such as nano-electronics, however, a 2D hybrid structure is preferred, which demands an alternative means for fabricating periodic patterns on CNTs.

The physical vapor deposition (PVD) technique is used widely for solid surface study. Upon heating under vacuum, metals/polymers decompose into small particles/oligomers and deposit on solid surfaces. See e.g. Wittmann, J. C. and Lotz, B., J. Mater. Sci., 1986, 21, 659-668. Gold has been used as the evaporation source to decorate polymer surfaces in order to reveal fine surface topography. Bassett, G. A., Philos. Magn., 1958, 3, 1042-1045; and Bassett, G. A. et al., Macro. Sci. Phys. 1967, B1, 161-184. PE has also been used to investigate polymer surfaces. Wittmann, J. C. et al., Makromol. Chem., Rapid Commun., 1982, 3, 733-738; Wittmann, J. C. and Lotz, B., J. Polym. Sci., Polym. Phys. Ed., 1985, 23, 205-226; Li, C. Y.; Yan, D. H. et al., Macromolecules, 1999, 32, 524-527; Li, C. Y. et al., Phys. Rev. Lett., 1999, 83, 4558-4561; Li, C. Y. et al., J. Am. Chem. Soc., 2000, 122, 72-79; and Li, C. Y. et al., Macromolecules, 2001, 34, 3634-3641. Upon heating under vacuum, PE degrades into oligomers that form rod-shaped single crystals. The orientation of the rods is particularly sensitive to the substrate surface feature. Polymer single-crystal sectorization and chain folding have been investigated successfully using this technique.

Accordingly, it is an object of certain embodiments of the present invention to provide an alternative method for the surface modification of carbon fibers and/or carbon nanotubes.

It is also an object of certain embodiments of the present invention to provide surface modified carbon fibers and/or carbon nanotubes having improved processability and/or solubility.

### SUMMARY OF THE INVENTION

In a first aspect, the present invention relates to a process for the modification of carbon fibers and/or carbon nanotubes, including 1-dimensional nanowire and nanofiber structures. In the process, polymeric material is deposited on a surface of the carbon fibers and/or carbon nanotubes using physical vapor deposition. The deposition process may be carried out under controlled conditions to produce a variety of useful modifications, including modifications at discrete intervals, as well as functional modifications.

In a second aspect, the present invention relates to carbon fibers, carbon nanowires, carbon nanotubes and nano-hybrid structures made by the modification processes of the present invention.

### BRIEF DESCRIPTION OF THE DRAWINGS

FIG. 1 is a schematic representation of the PVD experimental setup of Example 1. The CNTs were deposited on carbon coated glass slides before PVD.

FIG. 2 is a TEM image of PE-decorated SWNTs. The arrows indicate “centipede-shaped” 2D nanostructures, including an inset in the upper left-hand corner showing a “nano-necklace” structure.

FIG. 3 is a histogram analysis of the periodicity of 2D NHSK. 136 data points were measured from TEM micrographs by using a Scion Image.

FIGS. 4a-4f show AFM tapping-mode images of the PE-decorated SWNTs.

FIGS. 4a and 4b are height images of the 5 m and 2.5 m scan, respectively.

FIGS. 4c, 4d, and 4f are the height, amplitude, and top-view images of the 1 m scan, respectively.

FIG. 4e shows a height profile of the 2D NHSK along the SWNT axis.

FIG. 5a is AFM section analysis showing that the vertical distances of the PE rods are 9.6, 10.2 and 9.2 nm

FIG. 5b shows the height profile corresponding to FIG. 5a.

FIG. 6a is AFM section analysis shows vertical distances of 1.2 nm, 2.3 nm and 11.3 nm. 1.2 nm corresponds to the diameter of a single SWNT and 2.3 nm is probably due to formation of a small bundle of 2-4 SWNTs.

FIG. 6b is the height profile corresponding to FIG. 6a. At the center of one PE rod crystal, there is a small bump, which corresponds to the underneath SWNTs.

FIG. 7a is a schematic representation of the 2D NHSK.

FIGS. 7b, 7c, and 7d show the PE chain orientation on CNTs with different chirality. No matter whether the CNT possesses an armchair (7b), a zigzag (7c), or a chiral configuration (7d), PE chains are always parallel to the CNT axis.

FIG. 8a is TEM image of PE-decorated AD-MWNTs.

FIG. 8b shows an HRTEM image of a PE-decorated AD-MWNT. The MWNT was located in the hole region of a lacey carbon grid.

FIGS. 8c and 8d show TEM images of PE decorated on CVD-MWNT (FIG. 8c) and C18-MWNT (FIG. 8d).

FIG. 9 is TEM image of a 2D NHSK on a lacy carbon grid.

### DETAILED DESCRIPTION OF THE PREFERRED EMBODIMENTS

In a first aspect, the present invention relates to a method for the surface modification of CFs and CNTs, including 1-dimensional nanowire and nanofiber structures. In the method, the technique of polymer physical vapor deposition (“PVD”) is employed. It is envisaged that a polymeric material can be deposited on a surface of CNTs. The deposited polymer could be used to provide a form of surface modification. By controlling PVD conditions, polymeric materials can be associated with both single-walled and multi-walled CNTs (SWNTs and MWNTs). Moreover, the polymeric materials can be associated with the CNTs in various patterns in order to provide additional benefits.

Polymer nanocomposites with controlled tube-to-tube distance can also be prepared using the techniques of certain embodiments of the present invention. Since polymeric material can be easily removed by etching/dissolution, the method of the present invention provides a route for introducing multiple functionalities onto individual CNTs at well-defined intervals.

Any suitable polymeric material that can be deposited onto a carbon substrate by physical vapor deposition can be used in the present invention. Semi-crystalline polymers are one class of preferred materials. Suitable polymers may include polyolefins and nylons.

Preferred polymers are hydrophilic. Especially suitable polymers, include, but are not limited to, polypropylene, polyethylene, Nylon 6,6, polyethylene oxide, poly(vinylidene fluoride), poly-L-lysine and poly(phenylene sulfide).

The present method possesses the following advantages in forming patterned CNTs:

(1) the patterning is on individual CNTs and is relatively periodic; and

(2) the PVD process does not involve any solvent and is conducted at room temperature; and

(3) the resulting 2D NHSK can be adapted to create CNT-based nano-devices.

A wide range of vapor deposition temperatures and pressures may be used in the process of the present invention. For example, temperatures of from about 15° C. up to the crystallization temperature of the polymeric material can be employed. Pressures of from about 10⁻³ to about 10⁻³ torr can be employed. The 2D NHSK structures can also be used to fabricate polymer/CNT nano-composites with a controllable tube-to-tube distance. Deposition conditions can be controlled to provide the desired properties.

In addition, polymeric materials can be employed that can be removed by application of heat or solvent to allow further manipulation of the NHSKs by heat or solvent treatment. Polypyrrole can be synthesized on PE/CNT NHSKs by in situ surfactant-directed chemical oxidative polymerization. In a typical synthesis, surfactant cetyl trimethylammonium bromide and NHSK are mixed in deionized water and sonicated for over two hours to obtain well-dispersed suspensions. The mixture is then cooled to 0-5° C. A pre-cooled pyrrole monomer and an ammonium persulfate/deionized water solution are added sequentially to the suspension. The reaction mixture is ultrasonicated for about 2 minutes and then allowed to stand for about 10-20 hours. After filtration, polypyrrole coated NHSK is obtained. At this stage, CNTs are modified with both polyethylene and polypyrrole. Polyethylene can then be removed by hot p-xylene, resulting in polypyrrole functionalized CNTs.

The modification method of the present invention can be applied to carbon fibers, carbon nanotubes, carbon nanowires and similar devices. The modified CNTs of the present invention can be used, for example, to provide multi-functional nano-materials and enable the use of one-dimensional nanostructures in nano-electronics, photovoltaic cells and fuel cells, for example.

The carbon-containing material of the present invention can be located on a suitable substrate. Suitable solid substrates for coating carbon-containing material can be flexible and may be selected from glass, mica, silicon, and carbon-coated surfaces.

PE was used as a model polymer for deposition. The PE single-crystal rods generated during PVD were patterned uniformly on CNTs with the rod long axes perpendicular to the CNT axis. These rods also periodically span along the entire CNTs. This method may be employed to create complex CNT-based nano-architectures for nano-device applications.

### EXAMPLE 1

Single-walled carbon nanotube (SWNT)/dichlorobenzene (DCB) solution was spin-coated on a carbon-coated glass slide and decorated with PE using the PVD method. Purified HiPco SWNTs were purchased from Carbon Nanotechnologies Inc. Arch-discharged Multi-Walled Carbon Nanotubes (AD-MWNTs) were purchased from Aldrich and washed with 2.4 M nitric acid for 0.5 hrs. The resulting AD-MWNTs were then centrifuged, collected and dried in a vacuum oven. Linear polyethylene (PE, MFI=12 g/10 min) and 1, 2 dichlorobenzene (DCB) were purchased from Aldrich and used as received.

CNTs were dissolved in DCB (0.01 wt %) and sonicated for ˜2 hrs before dispersing on transmission electron microscopy (TEM) grids using spin coating. A Bransonic 8510R-DTH ultrasonic cleaner with a nominal frequency of 44±6 kHz at 250 W was used for ultrasonication. A small drop of CNT/DCB solution was first placed on the TEM grid. The spin speed and time were 3000 rpm and 60 s, respectively. These CNTs dispersed TEM grids or carbon coated cover glass were then coated by PE vapor using the physical vapor deposition method.

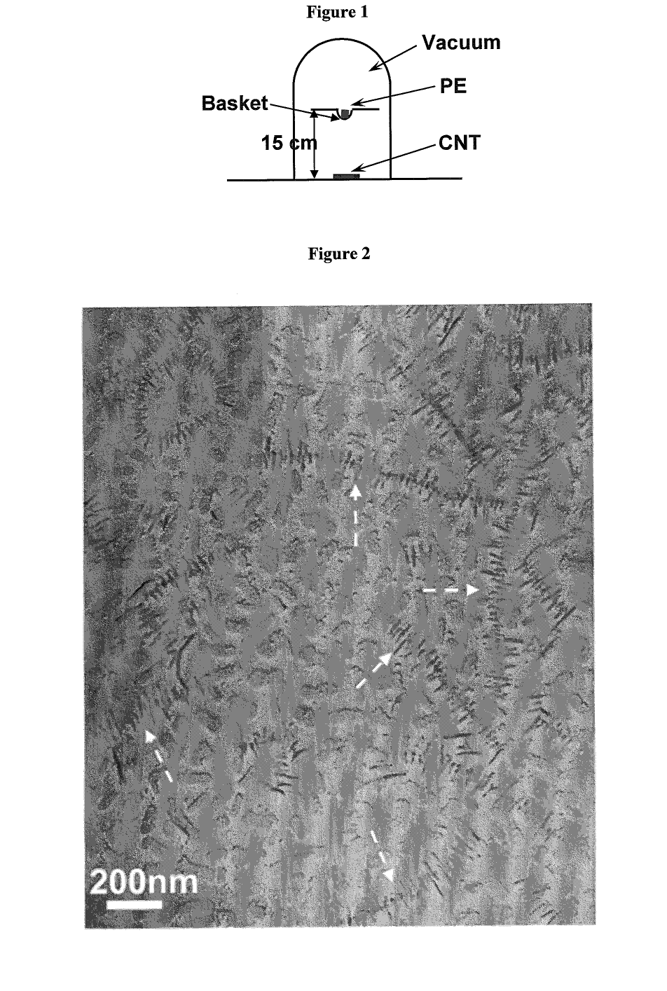

The experimental setup is shown in FIG. 1. A 15 cm distance between the substrate and the basket in the vacuum evaporator was chosen. Vacuum was controlled to be about 10⁻⁴-10⁻⁵ torr. The TEM gird was shadowed with Pt/Pd before TEM observation to enhance the contrast. TEM experiments were conducted using a JEOL-2000FX microscope with an accelerating voltage of 160 kV. High resolution TEM (HRTEM) experiments were carried out using a JEOL-2010F microscope with an accelerating voltage of 200 kV. AFM experiments was conducted using a Nanoscope IIIa atomic force microscope (AFM) (Digital Instruments/Veeco, Santa Barbara, Calif.), operated in tapping mode. Rectangular silicon nitride cantilevers (model TESPW, Digital Instruments/Veeco, Santa Barbara, Calif.) were used throughout the study.

FIG. 2 shows a transmission electron microscopy (TEM) micrograph of a PE-coated film. The sample was shadowed with a thin layer of Pt/Pd to enhance the contrast. Many small “islands” with an average height of 10 nm can be seen on the substrate (the height was estimated using the shadowing angle; it can also be confirmed by AFM 94 experiments. Of interest is that numerous “centipede-shaped” objects can be seen from the image, as indicated by the arrows. Careful examination of the image shows that these centipede-shaped objects are PE-coated SWNTs (or small SWNT bundles): the SWNTs seemingly form the body of the centipede-shaped objects, while PE forms the “feet” of the centipede-shaped objects. The so-called “feet” of the centipede-shaped objects are rod-shaped objects about 120 nm in length and 10 nm in width.

Unlike the rest of the PE materials formed on the carbon film, the PE rods attached to the SWNTs show uniform orientation and their long axes are perpendicular to the SWNT axes. Both the PE rods and SWNTs are 1D objects and the resulting centipede-shaped hybrid structure is 2D. 2D-NHSK was thus adopted to name this unique structure. These 2D structures may be more suitable for thin-film nanodevice applications.

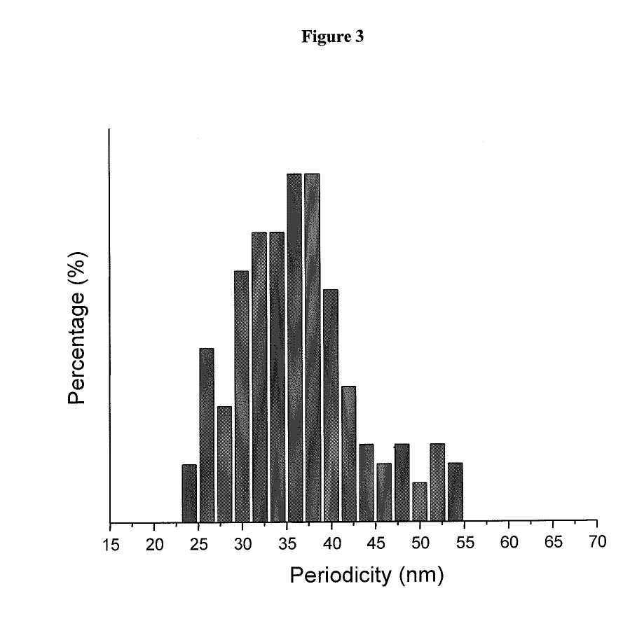

In PVD, PE chain scission occurs upon heating under vacuum (typically 10⁻⁴-10⁻⁵ Torr) and the resulting vaporized materials have a molecular weight (MW) on the order of 1300 g/mol. Wittmann, J. C. and Lotz, B., J. Polym. Sci., Polym. Phys. Ed., 1985, 23, 205-226; and Satou, M. et al., J. Polym. Sci., Part A-2, 1972, 10, 835-845. Upon deposition on the solid surface, these PE oligomers crystallize, resulting in the rod-shaped objects mentioned above, which are extended-chain PE crystals with the PE axis perpendicular to the longitudinal axis of the rod. Each PE rod has a width of about 10 nm, which corresponds to a molecular weight of about 1300 g/mol, in the extended-chain configuration. Most importantly, those PE crystal rods arrange periodically on individual SWNTs and have a periodicity of 37.4 (7.9 nm. A histogram of the 2D NHSK periodicity is shown in FIG. 3.

Although a few of PE nano-rods are slightly oblique from the axis, most rods are substantially perpendicular to the SWNT axis. The inset in the upper left-hand corner of FIG. 1 shows a TEM image of a “nano-necklace” structure formed by a PE decoration on a SWNT loop. Although the SWNT possesses an elliptical shape with a long axis of 200 nm and a short axis of 110 nm, rod-shaped PE crystals formed on the SWNT loop have their longitudinally axes oriented perpendicular to the local orientation of the SWNT axis. This suggests that the present PVD method can be adapted for patterning on complex CNT arrays, and the orientation of PE rods can be determined by the local CNT axis direction in such complex arrays.

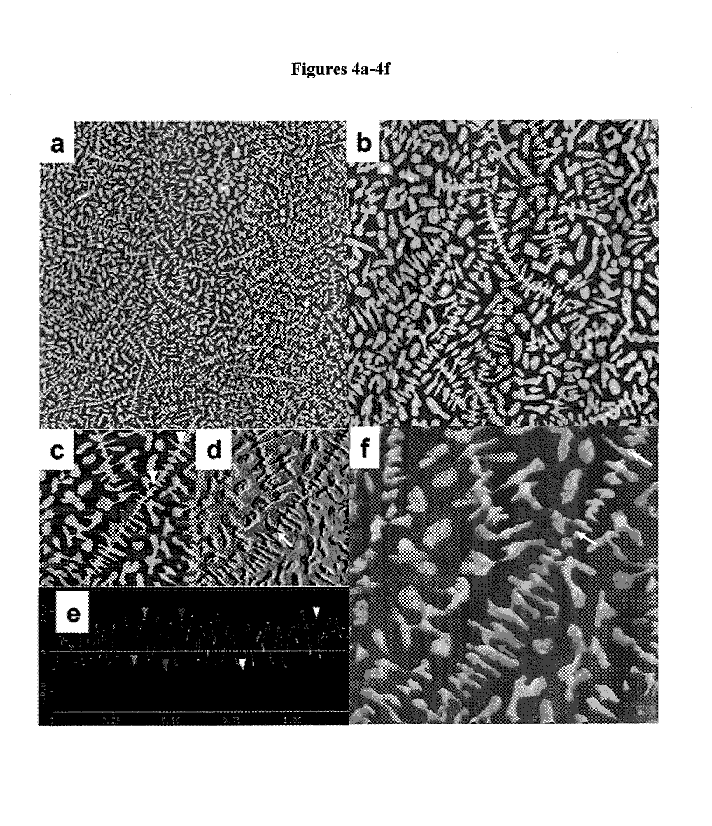

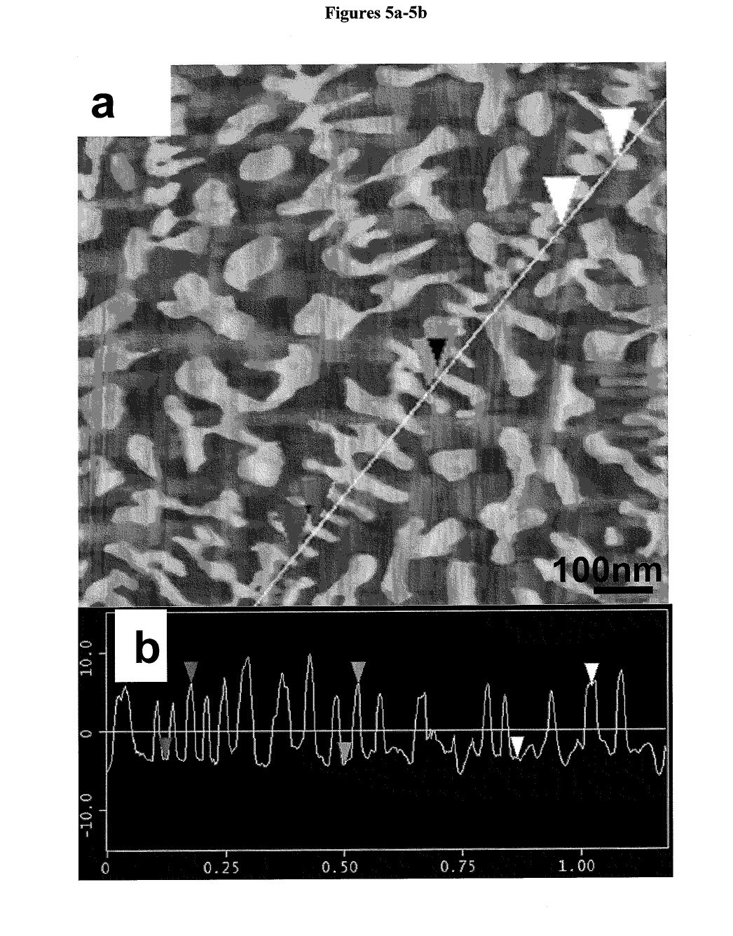

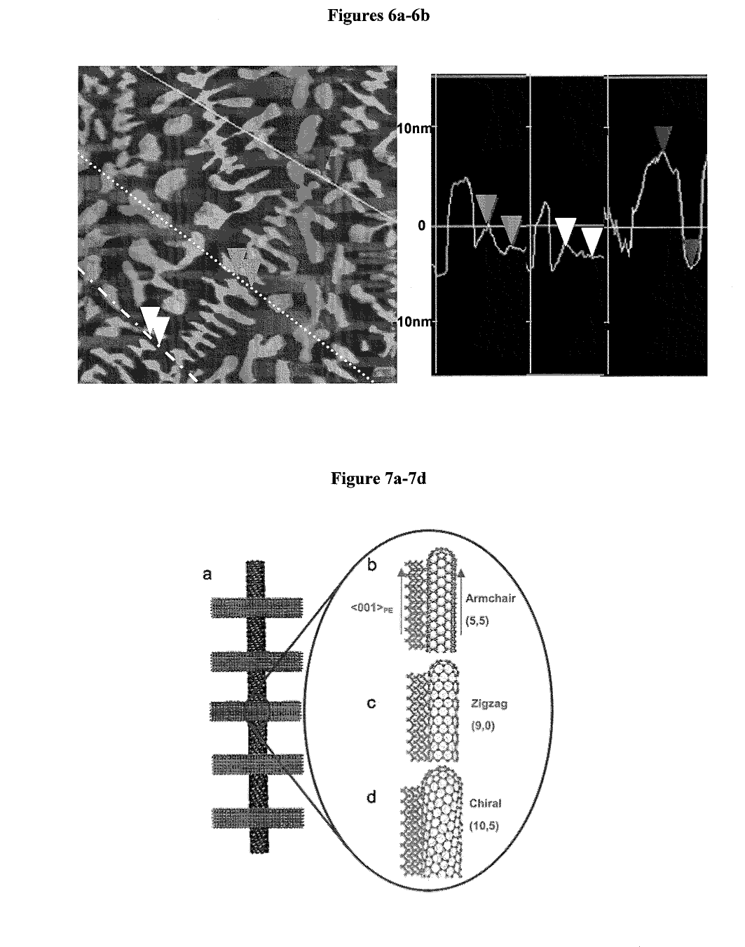

The 2D NHSK feature was confirmed by atomic force microscopy (AFM) experiments. FIGS. 4a-4f show the AFM 143 tapping-mode images of PE decoration on SWNTs. Scans [5 m (FIG. 4a) and 2.5 m (FIG. 4b)] show that the surface of PE-decorated SWNTs is flat. PE decoration is uniform, and all of the SWNTs are decorated with PE crystal rods. FIGS. 4c, 4d, and 4f are 1 m scans of the height, amplitude, and top-view images. PE rods substantially periodically span along the SWNT. An AFM height profile along the SWNT is shown in FIG. 4e. The average height measured from three different locations on one PE-decorated SWNT (indicated by the arrows in FIGS. 4e and 4f) is 12.4 nm, whereas the PE rods that are slightly off the 2D-NHSK center have an average height of 10 nm (FIGS. 5a-5b). This suggests that the SWNT possesses a diameter of 2.4 nm. Directly measuring the SWNT height in the interval regions of the PE rods (FIG. 6) confirms this result.

The relatively large diameter indicates small SWNT bundle formation (2-4 SWNTs for each bundle), which is not surprising because aggregation of SWNTs is dictated by the degree of exfoliation of SWNTs in DCB (more concentrated SWNT solutions tend to induce more and larger SWNT bundles). It should be noted that ridges between SWNTs in a bundle might facilitate the PE rod single-crystal growth. Nevertheless, 2D-NHSK can also be formed on single SWNTs as shown in the lower-left corner of FIG. 4c. The AFM height profile indicates that the tube diameter is 1.2 nm (FIG. 6), indicating the absence of SWNT agglomeration. Hence, formation of the 2D-NHSK is not significantly affected by SWNT aggregation. In all of these images, PE rods were formed on the top of these SWNTs bundles and were oriented substantially orthogonal with respect to the tube axis.

The orientation of the PE rods obtained in PVD has been used as a marker to determine the chain-folding direction in polymer single crystals. In the present case, orthogonal orientation of the rods and CNTs suggests that most of the PE oligomers are parallel to the CNT surface. Previous study showed that PE could grow epitaxially on graphite surfaces, and, in such case, the (110) plane of orthorhombic PE crystals grew parallel to the graphite substrate. The chain axis directions oriented in the 11-20 directions of the graphite surface layer. See e.g. Tuinstra, F. et al., Polym. Lett., 1970, 8, 861-865; Baukema, P. R. et al., J. Polym. Sci., Polym. Phys. Ed., 1982, 20, 399-4-9; and Tracz, A. et al., Macromol. Symp. 2001, 169, 129-135.

In the present case, however, the PE rods are predominantly oriented perpendicular to the CNT axis. Because the HiPco SWNT was used in this study and a variety of chiral configurations exist in these SWNTs, the uniform PE orientation suggests that epitaxy is not the determining factor for PE orientation. This might be due to the small diameter of the SWNTs: e.g. because the diameter of the CNTs is small, there are two factors determining PE chain orientation: epitaxy and geometry effect. Epitaxy requires a 001PE//11-20 graphite orientation. For CNTs with different chirality, following strict epitaxy, the PE chains should have different orientations (parallel or oblique to the tube axis). However, because SWNT possesses an extremely small diameter and the tube surface is thus curvy, geometric effects appear to require the PE chain to be parallel with the SWNT axis irrespective of the SWNT chirality.

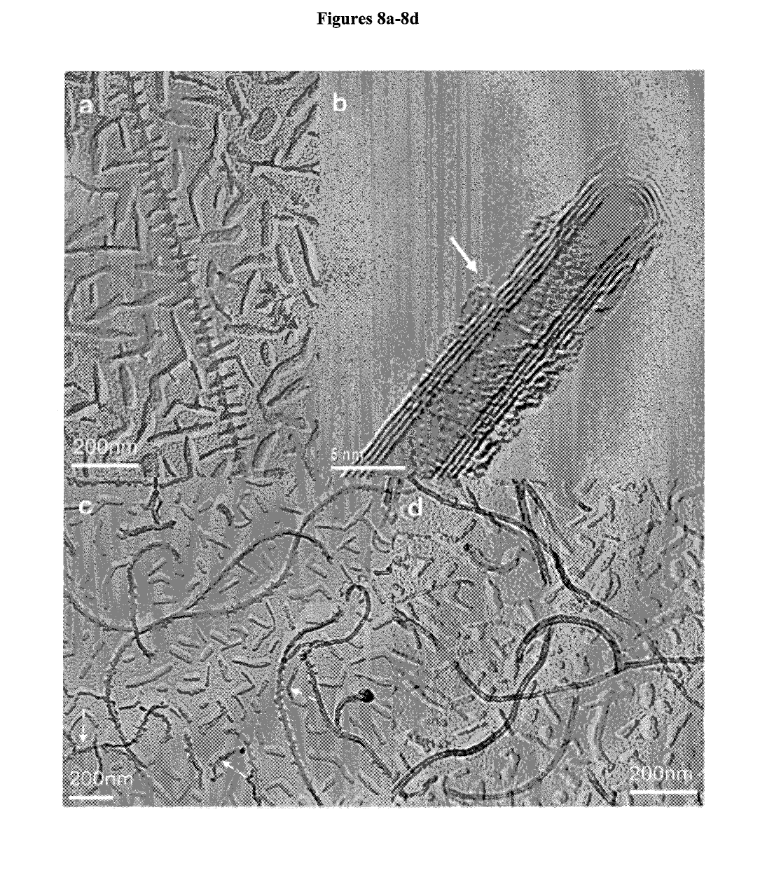

Observation of the exclusive orthogonal orientation between SWNT and PE rods suggests that geometric effects play the major role in determining PE chain orientation. FIGS. 7a-7d show the schematics of the 2D NHSK structure. In armchair (FIG. 7b), zigzag (FIG. 7c), and chiral (FIG. 7d) SWNTs, 001PE or PE chain orientation is always parallel to the SWNT axis.

This mechanism also holds in the case of multi-walled carbon nanotubes (MWNTs). FIGS. 8a-8d are TEM images of PE decoration on a MWNT [synthesized by arc discharge method (AD-MWNT), diameter 5-15 nm]. The morphology is similar to that of a SWNT, indicating that PVD is a generic method for different CNTs. Because the rods in 2D NHSK are PE oligomer crystals, it appears that two steps may be involved in the 2D NHSK formation process. In the first step, decomposed PE oligomers (MW 1300 g/mol) deposit on the solid surface, forming a thin layer on the substrate. During this step, PE oligomers coat the substrate uniformly regardless of the surface chemistry. In the second step, these oligomers self-organize to form single crystals. If the substrate is amorphous carbon, then random orientation of PE crystals is formed. In the CNT case, however, the CNT can provide nucleation sites. Nuclei formed on CNT and PE oligomers diffuse/crystallize upon these nuclei. The orientation of the nuclei dictates the final orthogonal orientation between PE rods and the CNT axis. Hence, the second step most likely involves surface diffusion and crystallization.

### EXAMPLE 2

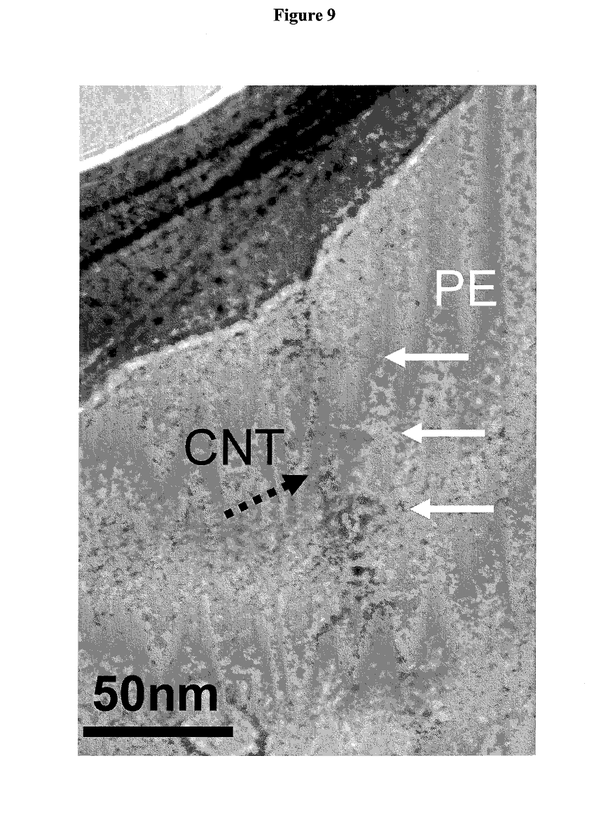

A lacey carbon grid consisting of a “broken” amorphous carbon film with numerous “holes” (3-5 m) to allow high-resolution TEM (HRTEM) observation was fabricated. By decorating PE on CNT-coated lacey carbon grids, because some of the CNTs dangle on the “holes” and thus are detached from the solid surface, PE oligomers cannot diffuse onto these CNTs to grow further into single crystals. Therefore, for all of the CNTs dangling on the “holes” of the lacey carbon grids, 2D NHSK should not form. Indeed, 2D NHSK was not observed in the “hole” region of the grids, and FIG. 8b shows an HRTEM image of such a MWNT. Three layers of the graphene sheets form the MWNT wall and on the MWNT surface, a layer of PE coating can be seen clearly as indicated by the arrows. The PE coating appears to be continuous and has an average thickness of about 1-2 nm. This continuous PE coating appears to be formed at the very beginning of this PVD process (step 1). Because CNTs are detached from the substrate, PE oligomers could not diffuse and grow further on the CNT surface. The PE oligomers already absorbed on the CNTs in step 1 also could not diffuse away from the CNT surface. The present image therefore captured the intermediate state of the 2D NHSK formation process. On the continuous carbon film area of this grid, the second step is allowed; hence, 2D NHSK structures were formed (FIG. 9). The two-step formation mechanism can therefore be confirmed from this experiment.

### EXAMPLE 3

Because the formation of the 2D NHSK was due to the nucleation of PE on the CNT surface, the structure and surface chemistry of the CNT might be major factors for PE crystal growth and preferred sidewall structure might be needed. To prove this, MWNTs synthesized by the chemical vapor deposition (CVD) method were used in a PE decoration study. FIG. 8c shows a TEM image of PE-decorated CVD-MWNTs. PE crystal rods also periodically decorated on MWNTs although they are not as uniform as those on the AD-MWNTs. In some areas, MWNTs were only partially decorated as indicated by the arrows. This might be due to the defect groups on the CVD-MWNT side walls.

### EXAMPLE 4

To further vary CNT wall structure, octadecylamine was covalently attached to the CVD-MWNT surface. More specifically, MWNTs (synthesized using chemical vapor deposition method) were provided by Nanostructured and Amorphous Materials, Inc. The diameter of the MWNT is about 8-15 nm. Concentrated H₂SO₄/HNO₃ Mixture (3:1) was used for oxidation. Esumi, K.; Ishigami, M.; Nakajima, A.; Swawda, K.; Honda, H. Carbon, 1996, 34,279-281 and Sun, Y.; Fu, K.; Lin, Y.; Huang, W. Acc. Chem. Res. 2002, 35, 1096-1104. The oxidation generated numerous surface acidic groups such as carboxylic acid groups. The carboxylic acid groups reacted with amine at higher temperature in the next amidation reaction. Chen, X.; Yoon, K.; Burger, C.; Sics, I.; Fang, D.; Hsiao, B. S.; Chu B. Macromolecules 2005 38, 3883-3893.

Qin, Y.; Liu, L.; Shi, J.; Wu, W.; Zhang, Jun.; Guo, Z.-X.; Li, Y. Zhu, D. Chem. Mater. 2003, 15, 3256-3260.

For the amidation reaction, the oxidized MWNTs were dispersed in octadecylamine and maintained at 180-190° C. under nitrogen for 24 hours.

FIG. 8d shows the TEM image of PE-decorated C18-MWNTs. It can be seen clearly that while the tubes are curvy, similar to FIG. 8c, the CNT surfaces are smooth and PE crystals did not form on the C18-MWNT surface. PE rod crystals formed on the free carbon surface. This indicates clearly that alkane-modified CNTs prohibit PE crystal growth on the CNT surface. It can therefore be concluded that the sidewall structure and surface chemistry of CNTs play a crucial role for successful PE decoration on CNTs. A uniform, smooth graphite-like surface is preferred for PE crystal formation.

The foregoing examples demonstrate that the PVD technique can be used for patterning polyethylene oligomers on CNTs. PE was decorated on the surface of SWNTs and MWNTs due to CNT initiated PE crystallization and the 2D NHSK was formed. A two-step formation mechanism of the 2D NHSK was confirmed. CNT sidewall structures and surface chemistry are determining factors for this hybrid structure formation.

It is to be understood that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

1. A method for modifying a surface of a carbon-containing substrate comprising the step of:
depositing at least one polymeric material on a surface of said carbon-containing substrate using physical vapor deposition to form a surface-modified carbon-containing substrate.

2. The method of claim 1, wherein said one-dimensional carbon containing-substrate is selected from the group consisting of a nanotube, a nanofiber, and a nanowire.

3. The method of claim 2, wherein said carbon-containing substrate is a one-dimensional carbon nanotube.

4. The method of claim 1, wherein said polymeric material comprises a hydrophilic polymer.

5. The method of claim 4, wherein said hydrophilic polymer is selected from the group consisting of polypropylene, polyethylene, Nylon 6,6, polyethylene oxide and poly(phenylene sulfide).

6. The method of claim 1, further comprising a step of patterning the surface-modified carbon-containing substrate.

7. The method of claim 6, wherein said patterning step comprises the step of crystallizing polymer at a plurality of nucleation sites located on said surface-modified carbon-containing substrate and orienting a plurality of crystals formed by said polymer crystallization step.

8. The method of claim 6, wherein said patterning step comprises forming and uniformly orienting a plurality of single-crystal rods having an axis substantially perpendicular to an axis of said one-dimensional carbon-containing substrate.

9. The method of claim 8, wherein said single-crystal rods have an interval periodicity of about 24 nm to about 55 nm.

10. The method of claim 8, wherein said single-crystal rods have an interval periodicity of about 23 nm to about 42.5 nm.

11. The method of claim 8, wherein said single-crystal rods have an interval periodicity of about 30 nm to about 40 nm.

12. The method of claim 1, wherein said step of physical vapor deposition comprises controlling an environmental factor selected from the group consisting of a vacuum pressure and a heating temperature, to produce a substantially periodic pattern.

13. The method of claim 1, wherein said polymeric material is oriented parallel to a surface of said carbon-containing substrate.

14. The method of claim 1, wherein said patterning step further comprises removing at least a portion of said polymeric material using a step selected from the group consisting of etching, solvent dissolution and heating.

15. The method of claim 6, wherein said patterning step further comprises covalently bonding a compound to a surface of said carbon containing substrate to inhibit localized polymeric crystallization.

16. The method of claim 1, wherein said step of physical vapor deposition is performed at room temperature and does not employ a solvent.

17. A nanohybrid material comprising a plurality of crystals attached to a carbon-containing substrate, wherein said crystals are formed by physical vapor deposition, and wherein said crystals are periodically located along an axis of said carbon-containing substrate.

18. The nanohybrid material of claim 17, wherein said crystals have an axis oriented substantially perpendicular to said axis of said carbon-containing substrate.

19. The nanohybrid material of claim 17, having a shape selected from the group consisting of a centipede-shape and a necklace-shape.

20. A carbon-containing structure made by the process of claim 1.
